(19) United States
(12) Patent Application Publication
(10) Pub. No.: US 2013/0075144 A1
(43) Pub. Date: Mar. 28, 2013

(54) PACKAGE SUBSTRATE WITH MESH PATTERN AND METHOD FOR MANUFACTURING THE SAME

(71) Applicants: Mi Jin PARK, Gyeonggi-do (KR); Seung Wook PARK, Gyeonggi-do (KR); Romero CHRISTIAN, Gyeonggi-do (KR)

(72) Inventors: Mi Jin PARK, Gyeonggi-do (KR); Seung Wook PARK, Gyeonggi-do (KR); Romero CHRISTIAN, Gyeonggi-do (KR)

(73) Assignee: Samsung Electro-Mechanics Co., Ltd., Suwon (KR)

(21) Appl. No.: 13/606,309

(22) Filed: Sep. 7, 2012

(30) Foreign Application Priority Data
Sep. 27, 2011 (KR) 10-2011-0097816

(51) Int. Cl. H05K 1/11; H05K 3/10

(52) U.S. Cl. 174/261; 29/846

(57) ABSTRACT

Disclosed herein are a package substrate and a method for manufacturing the same. According to an exemplary embodiment, there is provided a package substrate with a mesh pattern, including: a plurality of bonding pads forming sections connected with the outside; an insulating layer formed below the plurality of bonding pads; and a metallic layer placed below the insulating layer and having the mesh pattern in at least a partial area thereof and capacitance is provided by a combination of the mesh pattern and the insulating layer that infiltrates into a space for the mesh pattern. Further, there is provided a method for manufacturing the package substrate with the mesh pattern.

### CROSS REFERENCE(S) TO RELATED APPLICATIONS

This application claims the benefit under 35 U.S.C. Section 119 of Korean Patent Application Serial No. 10-2011-0097816, entitled “Package Substrate with Mesh Pattern and Method for Manufacturing the Same” filed on Sep. 27, 2011, which is hereby incorporated by reference in its entirety into this application.

### BACKGROUND OF THE INVENTION

1. Technical Field

The present invention relates to a package substrate and a method for manufacturing the same. More particularly, the present invention relates to a package substrate with a mesh pattern having an improved electrical characteristic and a method for manufacturing the same.

2. Description of the Related Art

Presently, with the small size, small thickness, and high density of electronic components, a printed circuit board has also been miniaturized, minutely patterned, and packaged. A package substrate configured with the packaging of the printed circuit board has a structure in which a metallic layer such as a wiring layer is formed on a base substrate, an insulating layer is formed on the metallic layer, and a bonding pad for connecting with an external semiconductor chip is installed on the insulating layer. In this case, in general, the metallic layer and the insulating layer are repetitively stacked to form a multilayer structure.

In the package substrate in the related art, as a bonding pattern of the metallic layer and the insulating layer in a lower part of a bonding section connected with the outside, i.e., the bonding pad is globally formed in not a mesh type but a non-mesh type, problems in reliability, such as interlayer separation or peeling or separation or peeling of the bonding pad, defective soldering, a crack of the bonding section, and the like occurred by stress.

### SUMMARY OF THE INVENTION

An object of the present invention is to improve product reliability and an electrical characteristic of a substrate through a mesh pattern of a metallic layer placed in a lower part of a bonding pad.

According to an exemplary embodiment of the present invention, there is provided a package substrate with a mesh pattern, including: a plurality of bonding pads forming sections connected with the outside; an insulating layer formed below the plurality of bonding pads; and a metallic layer placed below the insulating layer and having the mesh pattern in at least a partial area thereof.

Capacitance may be provided by combining the mesh pattern and the insulating layer that infiltrates into a space for the mesh pattern.

The bonding pads may be solder pads and the bonding pads may be connected with the outside by solders placed on the solder pads.

The metallic layer may be a signal line layer.

The mesh pattern may be formed at least in a vertical lower direction of the area for the bonding pads.

The package substrate may further include a solder resist layer applied in an uppermost part thereof so as to expose external connection sections of the plurality of bonding pads.

The package substrate may further include a core layer formed below the metallic layer.

The package substrate may be a double-sided substrate and the structure of the plurality of bonding pads, the insulating layer, and the metallic layer may be formed respectively in upper and lower parts of the double-sided substrate.

The package substrate may further include a core layer formed between the metallic layers in upper and lower parts of the double-sided substrate.

According to another exemplary embodiment of the present invention, there is provided a method for manufacturing a package substrate with a mesh pattern, including: (a) forming a metallic layer having the mesh pattern in at least a partial area thereof; (b) stacking an insulating layer on the metallic layer; and (c) forming, on the insulating layer, a plurality of bonding pads forming sections connected with the outside.

The package substrate may be manufactured to have capacitance by combining the mesh pattern and the insulating layer which infiltrates into a space for the mesh pattern by compression.

The metallic layer with the mesh pattern may be formed by etching a metallic film in step (a).

The metallic layer may be formed by preparing, in advance, a metal plate with the mesh pattern in step (a).

The area for the bonding pads may be formed at least in a vertical upper direction of the mesh pattern in step (c).

The method may further include (d) forming a solder resist layer on the insulating layer so as to expose external connection sections of the plurality of bonding pads, following step (c).

The method may further include forming a core layer, before step (a), and the metallic layer may be formed on the core layer in step (a).

The package substrate manufacturing method may be a double-sided substrate manufacturing method, and the stacked structure of the plurality of bonding pads, the insulating layer, and the metallic layer may be formed respectively in upper and lower parts of the double-sided substrate by performing steps (a) through (c) in upper and lower directions of the double-sided substrate.

### BRIEF DESCRIPTION OF THE DRAWINGS

FIG. 1 is a cross-sectional view schematically showing a package substrate with a mesh pattern according to one exemplary embodiment of the present invention;

FIG. 2 is a cross-sectional view schematically showing a mesh pattern of a package substrate with the mesh pattern according to one exemplary embodiment of the present invention;

FIG. 3 is a circuit diagram schematically describing an electrical characteristic of the package substrate with the mesh pattern according to one exemplary embodiment of the present invention;

FIG. 4 is a diagram schematically showing a package substrate with a mesh pattern according to another exemplary embodiment of the present invention;

FIGS. 5A to 5D are diagrams schematically showing a manufacturing process of a package substrate with a mesh pattern according to one exemplary embodiment of the present invention; and

FIGS. 6A to 6D are diagrams schematically showing a manufacturing process of a package substrate with a mesh pattern according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

It will be understood that when an element is simply referred to as being ‘connected to’ or ‘coupled to’ another element without being ‘directly connected to’ or ‘directly coupled to’ another element in the present description, it may be ‘directly connected to’ or ‘directly coupled to’ another element or be connected to or coupled to another element, having the other element intervening therebetween. In addition, in the specification, spatially relative terms, ‘on’, ‘above’, ‘upper’, ‘below’, ‘lower’, or the like, they should be interpreted as being in a ‘direct-contact’ shape or a shape in which other elements may be interposed therebetween, without a description that an element is in a ‘direct-contact’ with an object to be a basis. Furthermore, the spatially relative terms, ‘on’, ‘above’, ‘upper’, ‘below’, ‘lower’, or the like, may be used for describing a relationship of an element for another element. In this case, when a direction of the element to be a basis is reversed or changed, the spatially relative terms may include concept for directions of relative terms corresponding thereto.

Although a singular form is used in the present description, it may include a plural form as long as it is opposite to the concept of the present invention and is not contradictory in view of interpretation or is used as clearly different meaning.

It should be understood that “include”, “have”, “comprise”, “be configured to include”, and the like, used in the present description do not exclude presence or addition of one or more other characteristic, component, or a combination thereof.

In addition, the drawings referred to in the specification are ideal views for explaining embodiments of the present invention. In the drawings, the sizes, the thicknesses, or the like of films, layers, regions or the like may be exaggerated for clarity. Furthermore, the shapes of the illustrated regions in the drawings are for illustrating specific shapes and are not for limiting the scope of the present invention.

In addition, the drawings referred to in the specification are ideal views for explaining embodiments of the present invention. In the drawings, the sizes, the thicknesses, or the like of films, layers, regions or the like may be exaggerated for clarity. Furthermore, the shapes of the illustrated regions in the drawings are for illustrating specific shapes and are not for limiting the scope of the present invention.

First, a package substrate with a mesh pattern according to first exemplary embodiments of the present invention will be described in detail with reference to the accompanying drawings.

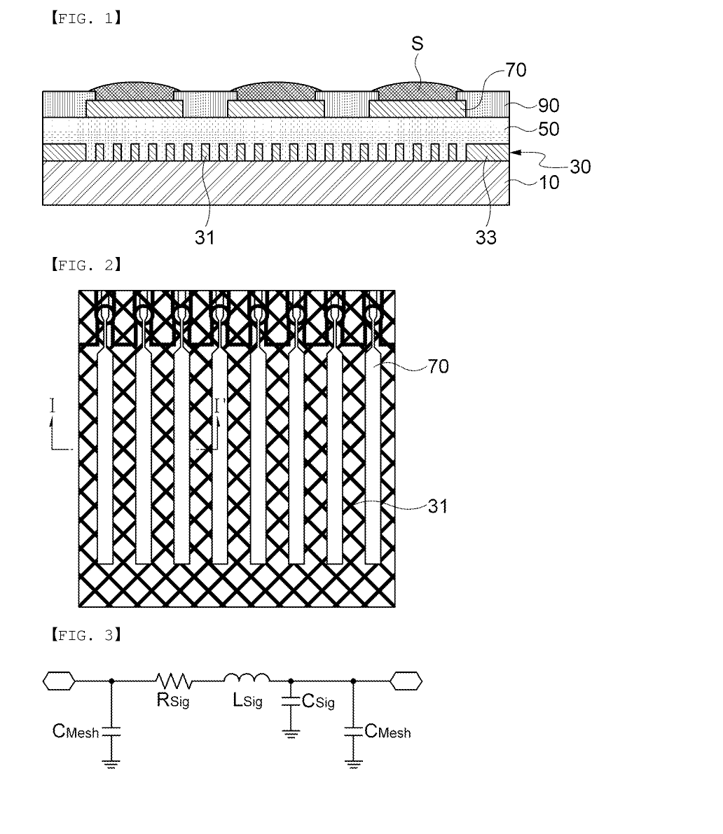

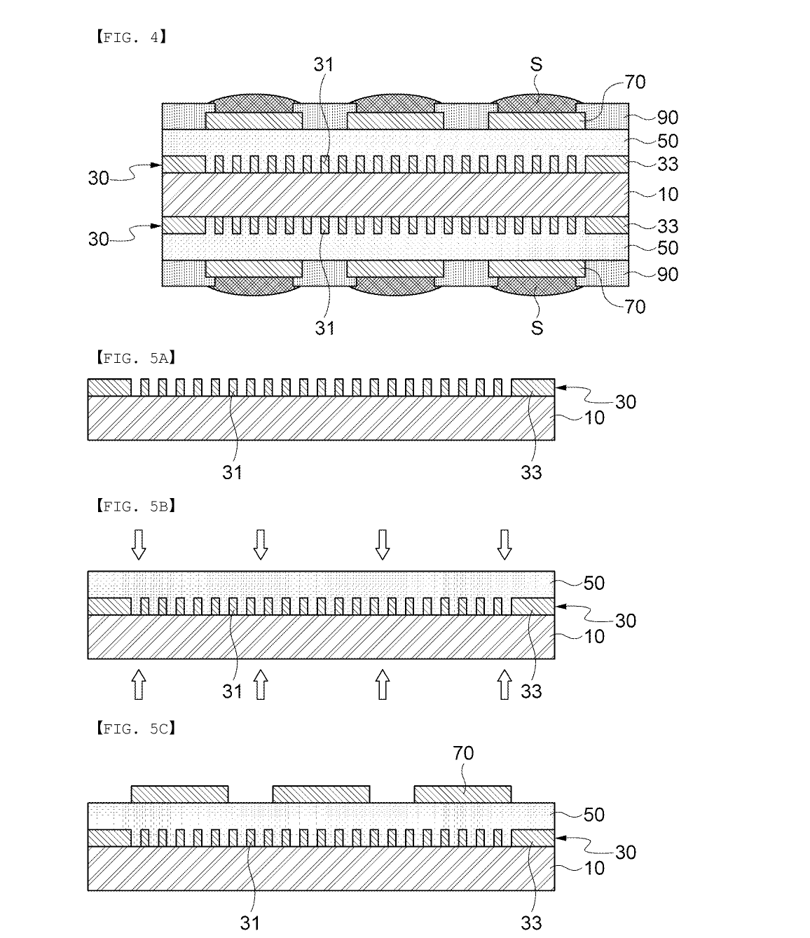

FIG. 1 is a cross-sectional view schematically showing a package substrate with a mesh pattern according to one exemplary embodiment of the present invention, FIG. 2 is a cross-sectional view schematically showing a mesh pattern of a package substrate with the mesh pattern according to one exemplary embodiment of the present invention, and FIG. 4 is a diagram schematically showing a package substrate with a mesh pattern according to another exemplary embodiment of the present invention.

Referring to FIG. 1, the package substrate with the mesh pattern according to one exemplary embodiment of the present invention includes a plurality of bonding pads 70, an insulating layer 50, and a metallic layer 30. According to one example, the package substrate may further include a core layer 10 as shown in FIG. 1. Further, in one example, the package substrate with the mesh pattern may be a package substrate for mounting a semiconductor chip.

Referring to FIG. 1, the plurality of bonding pads 70 are formed on the top of the package substrate. The bonding pad 70s form sections connected with the outside, e.g., a semiconductor chip. In this case, solders S are bonded onto the bonding pads 70 to be bonded to electrode pads of the semiconductor chip or bond the semiconductor chip onto the bonding pads 70 in a flip chip bonding method. Further, the semiconductor chip may be connected onto the bonding pads 70 in a wire bonding method. That is, the substrate manufactured in the exemplary embodiment may be adopted in a BGA substrate, a WB substrate, a WLP substrate, an HDI substrate.

In one example, the bonding pads 70 may be solder pads. In this case, the solders S are placed on the solder pads and the solder pads may be connected with the outside, e.g., the semiconductor chip by the solders S.

Further, referring to FIG. 1, in another example, the package substrate may further include a solder resist layer 90 applied on an uppermost part of the package substrate to expose external connection sections of the plurality of boding pads 70 to the outside. In this case, the solder resist layer 90 may be made of a known solder resist material used in a semiconductor substrate.

Moreover, referring to FIG. 2, another example will be described. FIG. 2 is a diagram schematically showing a mesh pattern of a package substrate according to one exemplary embodiment of the present invention. For example, it may be understood that FIG. 1 is a cross-sectional view take along line I-I′ of FIG. 2. However, when FIG. 1 is taken along line I-I′ of FIG. 2, reference numeral 33 of FIG. 1 will not be shown. Referring to FIG. 2, the bonding pad 70 may have a stripe shape. In this case, the metallic layer 30 with the mesh pattern is formed below the plurality of bonding pads 70 having the stripe shape with the insulating layer 50 interposed therebetween. In this case, although not shown, in one example, the solder resist layer 90 is partially applied to each of the bonding pads 70 having the stripe shape, such that the plurality of external connection sections may be formed to be isolated from each other.

Continuously, referring to FIG. 1, the insulating layer 50 is formed below the plurality of bonding pads 70. In this case, as an insulating material for forming the insulating layer 50, a known material used for the substrate may be used.

In addition, referring to FIG. 1, the metallic layer 30 is placed below the insulating layer 50. In this case, the metallic layer 30 has a mesh pattern 31 formed in at least a partial area thereof. The insulating layer 50 infiltrates into a space for the mesh pattern 31 of the metallic layer 30. As a result, according to one example, a capacitance component is shown by combining the mesh pattern 31 of the metallic layer and the insulating layer 50 that infiltrates into the space for the mesh pattern 31. In one example, the metallic layer 30 may be formed on a base substrate or an interlayer insulating layer 50. That is, in this case, it may be understood that reference numeral 10 represents the base substrate or an insulating substrate or the interlayer insulating layer 50 in FIG. 1.

In one example, the area for the mesh pattern 31 of the metallic layer 30 may be formed in a regular grid pattern. In this case, the grid pattern may have a square shape or a rhombus shape.

According to one more detailed example, the metallic layer 30 with the mesh pattern 31 may be a signal line layer. In this case, the metallic layer 30 may be a Cu wiring layer or a layer using another known metal, in one example. Alternatively, in one example, a ground may be formed by using the metallic layer 30 with the mesh pattern 31. In this case, in another example, the signal line layer with the mesh pattern 31 may be formed above a ground layer with the mesh pattern 31 with the insulating layer 50 interposed therebetween.

Further, according to one exemplary embodiment, the package substrate may have an improved electrical characteristic by the capacitance generated by the mesh pattern 31 and the insulating layer 50 that infiltrates into the space for the mesh pattern 31.

FIG. 3 is a circuit diagram schematically describing an electrical characteristic of the package substrate with the mesh pattern according to one exemplary embodiment of the present invention. Referring to FIG. 3, in the package substrate according to one exemplary embodiment of the present invention, a capacitance component Cmesh depending on the mesh pattern 31 is shown in a serial connection structure of a resistance component Rsig and an inductance component Lsig and a parallel connection structure of a capacitor component Csig in a known structure. The package substrate has a new electrical characteristic by a parasitic capacitance component Cmesh applied to both terminals depending on the mesh pattern 31.

Referring to one exemplary embodiment, when a BGA substrate, a wire/bonding (W/B) substrate, a wafer level package (WLP) substrate, and a high density interconnection (HDI) substrate adopting the package substrate according to the exemplary embodiment are used, high-frequency performance can be improved as compared with the HDI substrate in the related art. The number of interconnection levels and interlayer bias are reduced by forming the mesh pattern 31 on the metallic layer 30 such as the signal line layer to cause the improved performance. Minute lines and spaces can be implemented by forming the metallic layer 30 with the mesh pattern 31. Therefore, more signal lines can be designed in the same space than other products, e.g., products such as an HDI, a BGA, and the like not adopting fine patterns, and as a result, the number of interconnection levels and the interlayer bias can be reduced. When the number of interconnection levels and the interlayer bias are reduced, parasitic components L, C, and R are reduced, and as a result, the improved performance can be achieved. For example, at a frequency of 3.5 GHz or higher, RF loss is reduced as compared with the HDI substrate in the related art. The reason therefor is that the product according to the exemplary embodiment having a small interconnection length has a more excellent frequency characteristic in the high-frequency band than the HDI substrate in the related art because influences by the parasitic components L, C, and R increase.

Further, referring to one example, the area for the mesh pattern 31 of the metallic layer 30 may be formed at least in a vertical lower direction of the area for the bonding pads 70. For example, when the mesh pattern 31 is formed only in a partial area of the metallic layer 30, the area for the mesh pattern 31 is formed in the vertical lower direction of the area for the bonding pads 70. In one example, the mesh pattern 31 of the metallic layer 30 may be formed over the entire area of the metallic layer 30. In the exemplary embodiment, the mesh pattern 31 effectively prevents interlayer separation or peeling or separation or peeling of the pad or a crack of a bonding section caused by stress and shows a new electrical characteristic of the package substrate by forming new capacitance. Further, according to one example, as shown in FIG. 1, the metallic layer 30 may include the mesh pattern 31 and a non-mesh pattern 33. In this case, the mesh pattern 31 may be formed in the vertical lower direction of the area for the bonding pads 70 and the non-mesh pattern 33 may be formed in the vertical lower direction of an external area outside the bonding pad 70. For example, in one example, in the case where the area of the bonding pad 70 is in the range of 0.01 through 100 mmSQ, when the metallic layer 30 is formed below the bonding pad 70 with the insulating layer 50 interposed therebetween, the mesh pattern 31 may be formed partially or globally.

Further, referring to FIG. 1, in one example, a core layer 10 may be formed below the metallic layer 30. In the exemplary embodiment, reference numeral 10 represents the core layer. Further, according to one example, although not shown in FIG. 1, the insulating layer 50 may be additionally inserted between the metallic layer 30 and the core layer 10 or a composite structure of the insulating layer 50 and the metallic layer 30 with the mesh pattern 31 may be inserted between the metallic layer 30 and the core layer 10.

In this case, a core may be made of metal or an insulating material. In the exemplary embodiment, the core may be made of a known material. In one example, when the core is made of metal, the core layer 10 may become the ground. Alternatively, the metallic core layer may be a Vcc line.

Next, referring to FIG. 4, another exemplary embodiment of the package substrate with the mesh pattern will be described.

Referring to FIG. 4, in one example, the package substrate may be a double-sided substrate. In this case, the structure of the plurality of bonding pads 70, the insulating layer 50, and the metallic layer 30 may be formed respectively in upper and lower parts of the double-sided substrate.

Further, in one example, as shown in FIG. 4, the solder resist layer 90 may be applied onto the insulating layer 50 so as to expose the external connection sections of the bonding pads 70 in the upper and lower parts of the double-sided structure substrate.

According to the exemplary embodiments of the present invention, defective reliability of interlayer or intersolder separation or crack caused by stress like the related art and a tuning effect of an electrical signal by impedance matching with a capacitance value by the mesh pattern 31 may be expected.

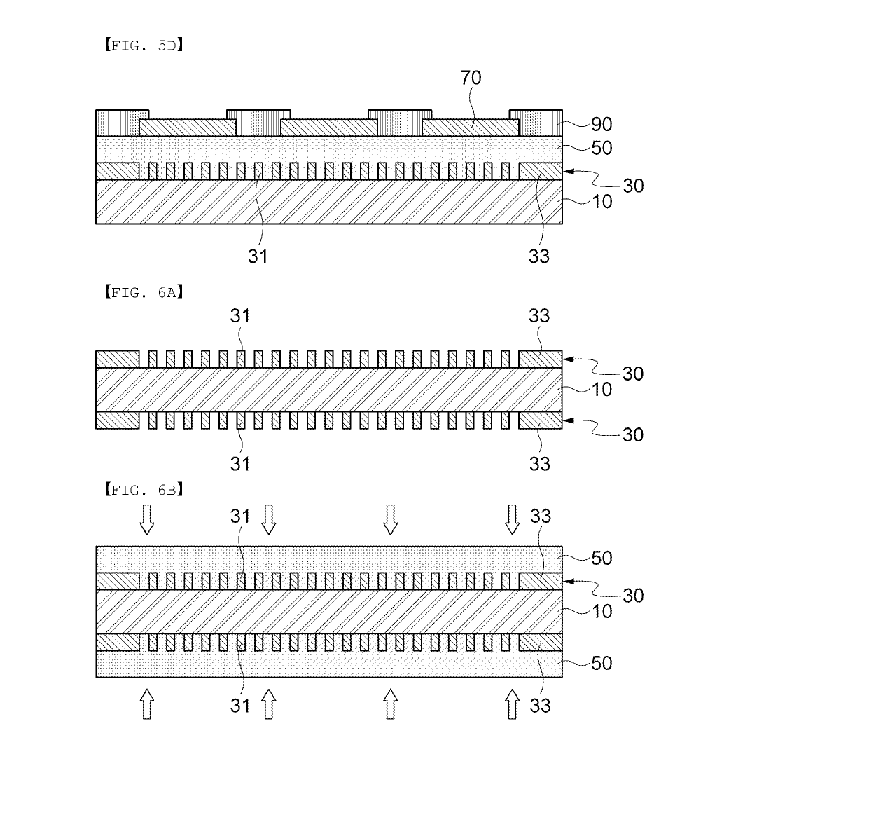

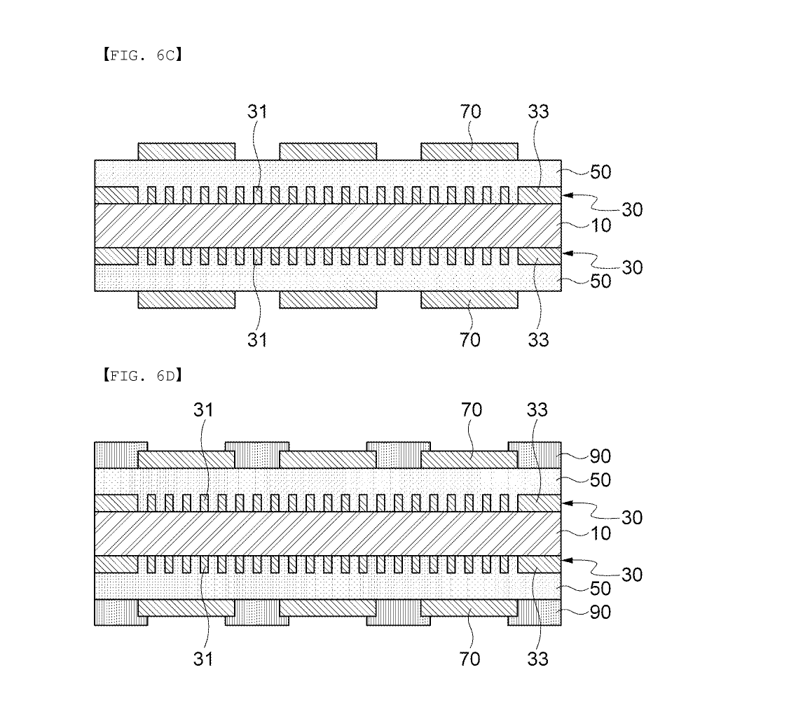

Next, a method for manufacturing a package substrate with a mesh pattern according to second exemplary embodiments of the present invention will be described in detail with reference to the accompanying drawings. In this case, FIGS. 5A through 5D and FIGS. 6A through 6D to be described below and the exemplary embodiments of the package substrate with the mesh pattern and FIGS. 1 through 4 will be referenced. Further, duplicated descriptions may be thus omitted.

FIGS. 5A to 5D are diagrams schematically showing a manufacturing process of a package substrate with a mesh pattern according to one exemplary embodiment of the present invention and FIGS. 6A to 6D are diagrams schematically showing a manufacturing process of a package substrate with a mesh pattern according to another exemplary embodiment of the present invention.

First, referring to FIGS. 5A through 5C, the method for manufacturing the package substrate with the mesh pattern according to one exemplary embodiment of the present invention may include steps (a) through (c) to be described below.

Referring to FIG. 5A, in step (a), a metallic layer 30 with a mesh pattern 31 is formed in at least a partial area. In this case, a metallic layer 30 may be formed on the top of a base layer or an interlayer of the package substrate. That is, in this case, it may be understood that reference numeral 10 shown in FIG. 5A represents a base substrate or an insulating substrate or an inter-insulating layer 50. Referring to FIG. 5A, in one example, the metallic layer 30 with the mesh pattern 31 may be formed on a core layer 10 and in this case, reference numeral 10 of FIG. 5A represents the core layer.

In this case, according to another detailed example, in step (a), the metallic layer 30 with the mesh pattern 31 may be formed by etching a metallic film.

Further, according to yet another example, in step (a), the metallic layer 30 may be formed by preparing a metal plate with the mesh pattern 31 in advance. For example, the metallic layer 30 may be formed by stacking the metal plate with the mesh pattern 31 in advance on the top of the base layer or the interlayer of the package substrate.

Further, referring to one example, in a postprocess, an area for the bonding pads 70 may be at least placed in a vertical upper direction of an area for the mesh pattern 31 of the metallic layer 30 formed in step (a). For example, in one example, when the metallic layer 30 formed in step (a) includes the mesh pattern 31 and a non-mesh pattern 33 as shown in FIG. 5A, the area for the bonding pads 70 is at least placed in the vertical upper direction of the area for the mesh pattern 31 and an external area outside the bonding pads 70 may be placed in a vertical upper direction of the non-mesh pattern 30. Although not shown, the metallic layer 30 formed in step (a) may include only the mesh pattern 31 without the non-mesh pattern 33. Further, in one example, in the case where the areas of the bonding pads 70 stacked in the postprocess is in the range of 0.01 to 100 mmSQ, the mesh pattern 31 may be formed on a part or over the entirety of the areas which the bonding pads 70 will be stacked.

According to one example, the metallic layer 30 with the mesh pattern 31 formed in step (a) may be a signal line layer. In this case, in one example, the metallic layer 30 may be a Cu wiring layer. Alternatively, in another example, the metallic layer 30 with the mesh pattern 31 formed in step (a) may be used as a ground. In this case, in yet another example, the insulating layer 50 is additionally formed above a ground layer with the mesh pattern 31 and thereafter, the signal line layer with the mesh pattern 31 may be formed on the top of the insulating layer 50.

Further, in one example, the core layer 10 may be formed before step (a) shown in FIG. 5A. In this case, the metallic layer 30 with the mesh pattern 31 may be formed according to step (a). In this case, reference numeral 10 shown in FIG. 5A represents the core layer 10.

Further, according to one example, although not shown in FIG. 5A, the additional insulating layer 50 may be stacked on the core layer 10 and thereafter, the metallic layer 30 with the mesh pattern 31 may be formed thereon or the composite structure in which the insulating layer 50 and the mesh pattern 31 shown in FIG. 5B are formed on the core layer 10 may be formed and thereafter, the metallic layer 30 with the mesh pattern 31 may be formed on the insulating layer 50 of the composite structure.

Next, referring to FIG. 5B, in step (b), the insulating layer 50 is stacked on the metallic layer 30 with the mesh pattern 31. In this case, the insulating layer 50 is stacked and thereafter, the insulating layer 50 infiltrates into a space for the mesh pattern 31 of the metallic layer 30 by compressing the stacked body through compression and/or heat.

As a result, in one example, capacitance is shown by combining the mesh pattern 31 of the metallic layer 30 and the insulating layer 50 that infiltrates into the space for the mesh pattern 31.

Continuously, referring to FIG. 5C, in step (c), the plurality of bonding pads 70 forming a section connected with the outside are formed on the insulating layer 50.

In this case, in another example, in step (c), the area for the bonding pads 70 may be at least formed in the vertical upper direction of the mesh pattern 31. Further, in one example, when the metallic layer 30 including the mesh pattern 31 and the non-mesh pattern 33 is formed in step (a), the bonding pads 70 may be formed so that the area for the bonding pads 70 is at least formed in the vertical upper direction of the mesh pattern 31 and the external area outside the bonding pads 70 is formed in the vertical upper direction of the non-mesh pattern 33.

Further, in one example, the bonding pads 70 may be solder pads connected with the outside by solders S.

In one example, the capacitance is shown by combining the mesh pattern 31 of the metallic layer 30 and the insulating layer 50 that infiltrates into the space for the mesh pattern 31. In this case, the package substrate may have an improved electrical characteristic by the capacitance.

Referring to FIG. 5D, in one example of the present invention, the method for manufacturing the package substrate with the mesh pattern may further include step (d) to be described below except for steps (a) through (c). In step (d), the solder resist layer 90 is formed on the insulating layer 50 so as to expose the external connection sections of the plurality of bonding pads 70 following step (c).

Next, referring to FIGS. 6A through 6C or FIGS. 6A through 6D, in yet another exemplary embodiments of the present invention, the method for manufacturing the package substrate with the mesh pattern may be a method for manufacturing a double-sided substrate. In this case, the processes in the exemplary embodiments described according to FIGS. 5A through 5C or FIGS. 5A through 5D may be performed on double sides of the substrate by the same method or the appropriate method, a duplicated description may be omitted.

For example, in one example, referring to FIGS. 6A through 6C, steps (a) through (c) may be performed in upper and lower directions of the double-sided substrate. According to the processes of FIGS. 6A through 6C, the plurality of bonding pads 70, the insulating layer 50, and the metallic layer 30 may be stacked in upper and lower parts of the double-sided substrate.

Further, referring to FIGS. 6A through 6D, the solder resist layer 90 may be formed on the insulating layer 50 so as to expose the external connection sections of the plurality of bonding pads 70 in the upper part of the double-sided substrate.

As set forth above, according to the exemplary embodiments of the present invention, product reliability and an electrical characteristic of a substrate can be improved through a mesh pattern of a metallic layer placed in a lower part of a bonding pad in a package substrate mounted with a semiconductor chip.

According to the exemplary embodiments of the present invention, as a relatively large area is wired in the mesh pattern, the product reliability can be improved by reducing defective reliability by product stress which occurred in the related art and further, tuning by impedance matching can be achieved improving an electrical characteristic caused by the mesh pattern.

It is apparent that various effects not directly described according to various exemplary embodiments of the present invention can be achieved by those skilled in the art from various components according to the exemplary embodiments of the present invention.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. In addition, the exemplary embodiments according to various combinations of the aforementioned configurations may be obviously implemented by those skilled in the art from the aforementioned detailed explanations. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

1. A package substrate with a mesh pattern, comprising:
a plurality of bonding pads forming sections connected with the outside;
an insulating layer formed below the plurality of bonding pads; and
a metallic layer placed below the insulating layer and having the mesh pattern in at least a partial area thereof.

2. The package substrate with a mesh pattern according to claim 1, wherein capacitance is provided by combining the mesh pattern and the insulating layer that infiltrates into a space for the mesh pattern.

3. The package substrate with a mesh pattern according to claim 1, wherein the bonding pads are solder pads, and
the bonding pads are connected with the outside by solders placed on the solder pads.

4. The package substrate with a mesh pattern according to claim 1, wherein the metallic layer is a signal line layer.

5. The package substrate with a mesh pattern according to claim 1, wherein the mesh pattern is formed at least in a vertical lower direction of the area for the bonding pads.

6. The package substrate with a mesh pattern according to claim 1, further comprising a solder resist layer applied in an uppermost part thereof so as to expose external connection sections of the plurality of bonding pads.

7. The package substrate with a mesh pattern according to claim 1, further comprising a core layer formed below the metallic layer.

8. The package substrate with a mesh pattern according to claim 1, wherein the package substrate is a double-sided substrate, and
the structure of the plurality of bonding pads, the insulating layer, and the metallic layer is formed respectively in upper and lower parts of the double-sided substrate.

9. The package substrate with a mesh pattern according to claim 2, wherein the package substrate is a double-sided substrate, and
the structure of the plurality of bonding pads, the insulating layer, and the metallic layer is formed respectively in upper and lower parts of the double-sided substrate.

10. The package substrate with a mesh pattern according to claim 8, further comprising a core layer formed between the metallic layers in upper and lower parts of the double-sided substrate.

11. A method for manufacturing a package substrate with a mesh pattern, the method comprising:
forming a metallic layer having the mesh pattern in at least a partial area thereof;
stacking an insulating layer on the metallic layer; and
forming, on the insulating layer, a plurality of bonding pads forming sections connected with the outside.

12. The method for manufacturing a package substrate with a mesh pattern according to claim 11, wherein capacitance is provided by combining the mesh pattern and the insulating layer that infiltrates into a space for the mesh pattern by compression.

13. The method for manufacturing a package substrate with a mesh pattern according to claim 11, wherein the metallic layer with the mesh pattern is formed by etching a metallic film in the forming a metallic layer having the mesh pattern in at least a partial area thereof.

14. The method for manufacturing a package substrate with a mesh pattern according to claim 11, wherein the metallic layer is formed by preparing a metal plate with the mesh pattern in the forming a metallic layer having the mesh pattern in at least a partial area thereof.

15. The method for manufacturing a package substrate with a mesh pattern according to claim 11, wherein the area for the bonding pads is formed at least in a vertical upper direction of the mesh pattern in the forming, on the insulating layer, a plurality of bonding pads forming sections connected with the outside.

16. The method for manufacturing a package substrate with a mesh pattern according to claim 11, further comprising forming a solder resist layer on the insulating layer so as to expose external connection sections of the plurality of bonding pads, following the forming, on the insulating layer, a plurality of bonding pads forming sections connected with the outside.

17. The method for manufacturing a package substrate with a mesh pattern according to claim 11, further comprising:
forming a core layer, before the forming a metallic layer having the mesh pattern in at least a partial area thereof,
wherein the metallic layer is formed on the core layer in the forming a metallic layer having the mesh pattern in at least a partial area thereof.

18. The method for manufacturing a package substrate with a mesh pattern according to claim 11, wherein the package substrate manufacturing method is a double-sided substrate manufacturing method, and
the stacked structure of the plurality of bonding pads, the insulating layer, and the metallic layer is formed respectively in upper and lower parts of the double-sided substrate by performing the forming a metallic layer having the mesh pattern in at least a partial area thereof, the stacking an insulating layer on the metallic layer, and the forming, on the insulating layer, a plurality of bonding pads forming sections connected with the outside in upper and lower directions of the double-sided substrate.

19. The method for manufacturing a package substrate with a mesh pattern according to claim 12, wherein the package substrate manufacturing method is a double-sided substrate manufacturing method, and
the stacked structure of the plurality of bonding pads, the insulating layer, and the metallic layer is formed respectively in upper and lower parts of the double-sided substrate by performing the forming a metallic layer having the mesh pattern in at least a partial area thereof, the stacking an insulating layer on the metallic layer, and the forming, on the insulating layer, a plurality of bonding pads forming sections connected with the outside in upper and lower directions of the double-sided substrate.

20. The method for manufacturing a package substrate with a mesh pattern according to claim 17, wherein the package substrate manufacturing method is a double-sided substrate manufacturing method, and
the stacked structure of the plurality of bonding pads, the insulating layer, and the metallic layer is formed respectively in upper and lower parts of the double-sided substrate by performing the forming a metallic layer having the mesh pattern in at least a partial area thereof, the stacking an insulating layer on the metallic layer, and the forming, on the insulating layer, a plurality of bonding pads forming sections connected with the outside in upper and lower directions of the double-sided substrate.
